(19) United States
(12) Patent Application Publication
(10) Pub. No.: US 2025/0146119 A1
(43) Pub. Date: May 8, 2025

(54) DUAL COLLIMATOR PHYSICAL VAPOR DEPOSITIONS PROCESSING CHAMBER

(71) Applicant: Applied Materials, Inc., Santa Clara, CA (US)

(72) Inventors: Martin Lee RIKER, Milpitas, CA (US); Abilash SAINATH, Bangalore (IN); Suhas UMESH, Santa Clara, CA (US); Keyvan KASHEFIZADEH, Santa Clara, CA (US); Yunho KIM, Milpitas, CA (US); Sundarapandian Ramaling Vijayalaskshmi REDDY, Bangalore (IN); Prashanth KOTHNUR, San Jose, CA (US)

(21) Appl. No.: 18/939,220

(22) Filed: Nov. 6, 2024

(30) Foreign Application Priority Data
Nov. 7, 2023 (IN) 202341075951

(51) Int. Cl. C23C 14/02; C23C 14/35

(52) U.S. Cl. CPC C23C 14/024; C23C 14/35

(57) ABSTRACT

In some embodiments, a physical vapor deposition apparatus includes a top flux optimizer configured to be biased. The physical vapor deposition apparatus further includes an intermediate flux optimizer configured to be biased. The top flux optimizer and the intermediate flux optimizer are separated by a first distance. The physical vapor deposition apparatus further includes a bottom flux optimizer configured to be biased. The bottom flux optimizer and the intermediate flux optimizer are separated by a second distance. The physical vapor deposition apparatus further includes a top power source coupled to the top flux optimizer, an intermediate power source coupled to the intermediate flux optimizer, and a bottom power source coupled to the bottom flux optimizer.

### CROSS-REFERENCE TO RELATED APPLICATIONS

This application claims benefit of an India provisional patent application number 202341075951, filed Nov. 7, 2023, which is herein incorporated by reference.

### BACKGROUND

### Field

Embodiments of the present disclosure generally relate to physical vapor deposition (PVD) film formation on substrates in a device fabrication process, and more particularly, to apparatus and methods for depositing one or more film layers in features formed on a substrate.

### Description of the Related Art

The field of semiconductor device fabrication is constantly evolving, with new materials, processes, and equipment being developed to meet the growing demand for smaller, faster, and more complex devices. One of the key challenges in device fabrication is the need to deposit thin films of various materials with high quality, uniformity, and precision.

Physical vapor deposition (PVD) is a common technique used for depositing thin films of various metals and metal alloys. However, PVD deposition can cause damage to the underlying layers of the substrate, particularly when high-energy ions are used to enhance the deposition rate or when the substrate features are small and have high aspect ratios. This damage can lead to poor step coverage and other defects, which can compromise the performance and reliability of the device.

Therefore, there is a need for an improved deposition apparatus that can provide high-quality, and uniform thin films without compromising the performance and reliability of the formed device.

### SUMMARY

Embodiments of the present disclosure generally relate to physical vapor deposition (PVD) film formation on substrates in a device fabrication process, and more particularly, to apparatus and methods for depositing one or more film layers in features formed on a substrate.

In some embodiments, a physical vapor deposition apparatus includes a substrate support disposed within a processing region of a processing chamber of the physical vapor deposition apparatus. The substrate support includes a substrate supporting surface. The physical vapor deposition apparatus further includes a first flux optimizer disposed within the processing region. The first flux optimizer includes a plurality of apertures extending there through and is configured to be biased relative to a ground reference. The physical vapor deposition apparatus further includes a second flux optimizer disposed within the processing region. The second flux optimizer includes a plurality of apertures extending there through and is configured to be biased relative to the ground reference. The second flux optimizer is disposed between the first flux optimizer and the substrate support. The physical vapor deposition apparatus further includes a first power source coupled to the first flux optimizer or the second flux optimizer. The first power source is configured to supply a voltage to either the first flux optimizer or the second flux optimizer. The first power source is configured to generate a bias voltage between the first flux optimizer and the second flux optimizer.

In some embodiments, a physical vapor deposition apparatus includes a top flux optimizer configured to be biased. The physical vapor deposition apparatus further includes an intermediate flux optimizer configured to be biased. The top flux optimizer and the intermediate flux optimizer are separated by a first distance. The physical vapor deposition apparatus further includes a bottom flux optimizer configured to be biased. The bottom flux optimizer and the intermediate flux optimizer are separated by a second distance. The physical vapor deposition apparatus further includes a top power source coupled to the top flux optimizer, an intermediate power source coupled to the intermediate flux optimizer, and a bottom power source coupled to the bottom flux optimizer.

In some embodiments, a method for depositing a film onto a substrate includes applying a bias to at least one of a plurality of biasable flux optimizers disposed in a processing region of a processing chamber by supplying a voltage thereto. The voltage is supplied by a power source. At least one of the plurality of biasable flux optimizers is grounded. The plurality of biasable flux optimizers are positioned within the processing region between a sputtering target and a substrate support. The method further includes forming a film on a surface of a substrate disposed on the substrate support by sputtering a target material from the sputtering target by applying a bias to the target.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic top view of an exemplary processing system according to an embodiment.

FIG. 2A is a cross-sectional view of an exemplary processing chamber according to an embodiment.

FIG. 2B is a cross-sectional view of an exemplary processing chamber according to an embodiment.

FIG. 3A is a perspective view of a biasable flux optimizer, according to an embodiment.

FIG. 3B is a perspective view of a biasable flux optimizer, according to an embodiment.

FIG. 3C is a top view of a biasable flux optimizer, according to an embodiment.

FIG. 3D is a cross-sectional view of a biasable flux optimizer, according to an embodiment.

FIG. 4 is a cross-sectional view of an exemplary processing chamber according to an embodiment.

FIG. 5 is a process flow diagram of a method, according to an embodiment.

FIG. 6 is an illustrative representation of copper ion flux relative to the distance from the substrate, according to an embodiment.

FIG. 7 is an illustrative representation of copper ion flux relative to the distance from the substrate, according to an embodiment.

FIG. 8 is a cross-sectional representation of a processing region within a processing chamber according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure include an apparatus that includes a physical vapor deposition (PVD) chamber design that includes a Flux Optimizer (e.g., collimator) design that can be used to form thin films on a surface of a substrate that includes a plurality of features formed thereon. Embodiments of the invention generally provide a processing chamber used to perform a PVD process useful for forming metal interconnects within the features formed on the substrate. In one embodiment, the process chamber design is adapted to deposit a desired material using a multistep PVD process. The processing chamber disclosed herein may be especially useful for depositing films so that they have an improved deposition uniformity, feature side wall coverage and feature bottom coverage. The processing chamber's design features may include a biasable flux optimizer (e.g., collimator), one or more side wall electromagnets, an improved magnetron design, an improved substrate biasing configuration, and an improved process kit design.

### Exemplary Processing System

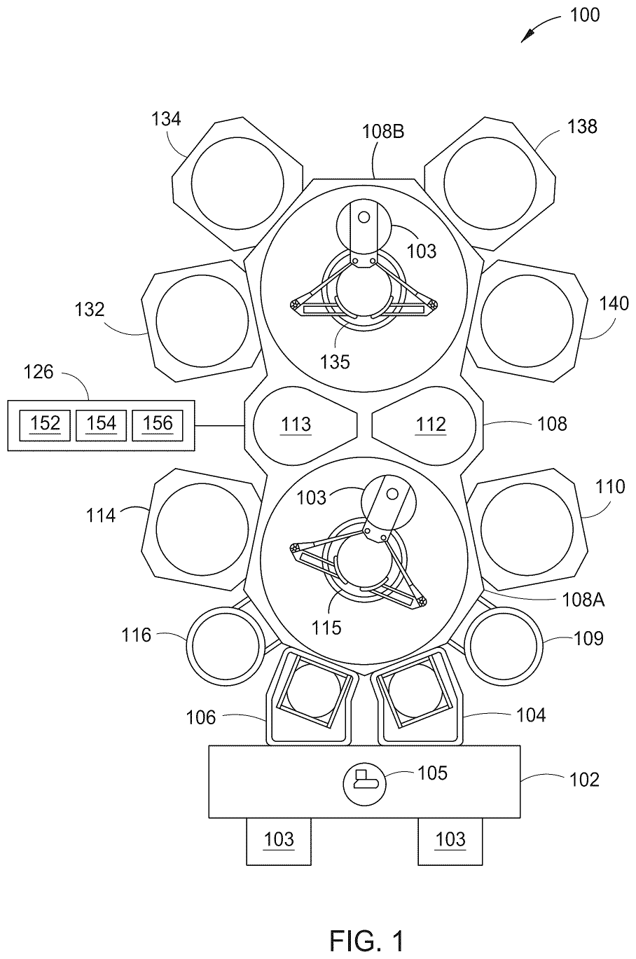

FIG. 1 is a schematic top view of an exemplary processing system 100 (also referred to as a “processing platform”), according to certain embodiments. The processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the FOUPs 103 to at least one of the first load lock chamber 104 or the second load lock chamber 106. Proceeding counterclockwise around the transfer chamber 108 from the buffer portion 108A of the first load lock chamber 104, the processing system 100 includes a first degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114 and the pass-through chambers 112, 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, and a fourth processing chamber 138. In general, the processing chambers 132, 134, 136, 138 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138 are a PVD chamber that configured similar to the processing chamber 200 described below.

The buffer portion 108A and back-end portion 108B of the transfer chamber 108 and each chamber coupled to the transfer chamber 108 are maintained at a vacuum state. As used herein, the term “vacuum” may refer to pressures less than 760 Torr, and will typically be maintained at pressures near 10-5 Torr (i.e., ˜10-3 Pa). However, some high-vacuum systems may operate below near 10-7 Torr (i.e., ˜10-5 Pa). In certain embodiments, the vacuum is created using a rough pump and/or a turbomolecular pump coupled to the transfer chamber 108 and to each of the one or more process chambers (e.g., process chambers 109-138). However, other types of vacuum pumps are also contemplated.

A system controller 126, such as a programmable computer, is coupled to the processing system 100 for controlling one or more of the components therein. For example, the system controller 126 may control the operation of the processing chamber 200, which is described further below. In operation, the system controller 126 enables data acquisition and feedback from the respective components to coordinate processing in the processing system 100. The system controller 126 includes a programmable central processing unit (CPU) 152, which is operable with a memory 154 (e.g., non-volatile memory) and support circuits 156. The support circuits 156 (e.g., cache, clock circuits, input/output subsystems, power supplies, etc., and combinations thereof) are conventionally coupled to the CPU 152 and coupled to the various components within the processing system 100.

In some embodiments, the CPU 152 is one of any form of general purpose computer processor used in an industrial setting, such as a programmable logic controller (PLC), for controlling various monitoring system component and sub-processors. The memory 154, coupled to the CPU 152, is non-transitory and is typically one or more of readily available memory such as random access memory (RAM), read only memory (ROM), floppy disk drive, hard disk, or any other form of digital storage, local or remote.

Herein, the memory 154 is in the form of a computer-readable storage media containing instructions (e.g., non-volatile memory), that when executed by the CPU 152, facilitates the operation of the processing system 100. The instructions in the memory 154 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

### Processing Chamber Example(s)

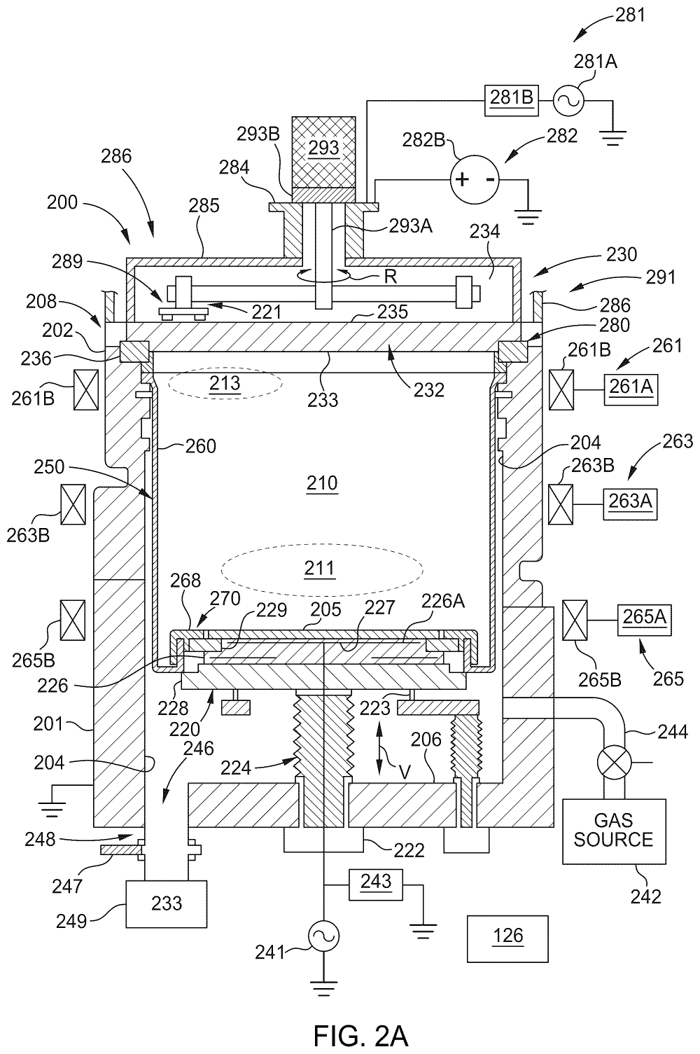

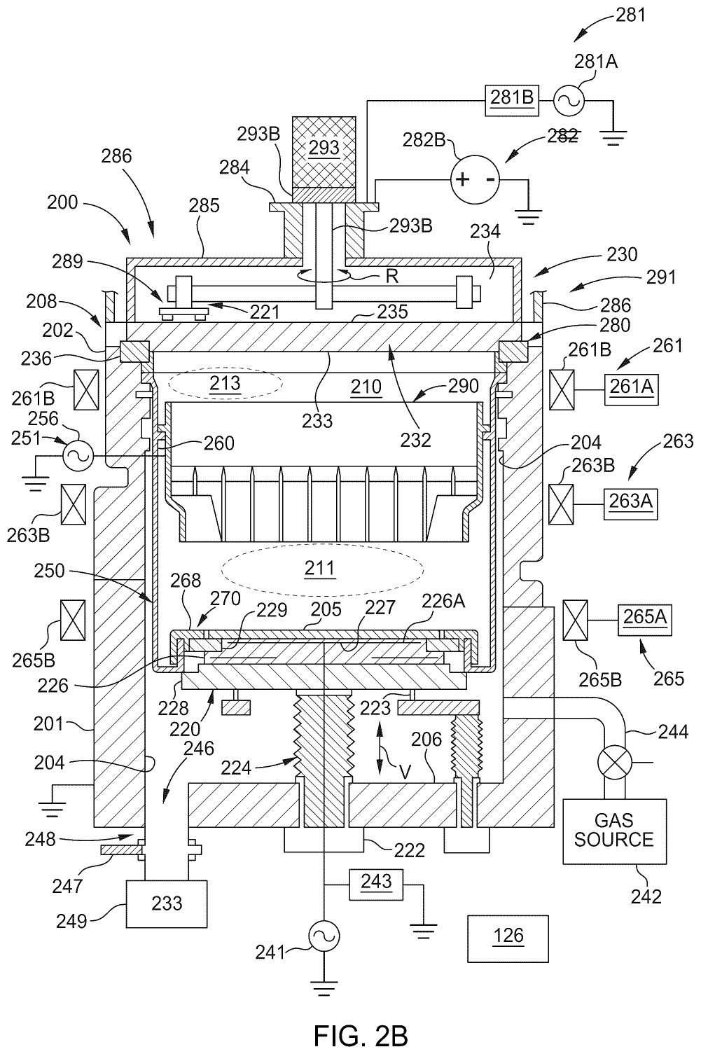

FIG. 2A illustrates an exemplary processing chamber 200 having an upper process assembly 208, a process kit 250 and a pedestal assembly 220, which are all configured to process a substrate 205 disposed in a processing region 210. The process kit 250 includes a one-piece grounded shield 260, a deposition ring 268, a cover ring 270, and an isolator ring assembly 280. In the version shown, the processing chamber 200 comprises a sputtering chamber, also called a PVD chamber, capable of depositing a single or multi-compositional material from a sputtering target 232 on the substrate 205. The processing chamber 200 may also be used to deposit aluminum (Al), copper (Cu), nickel (Ni), platinum (Pt), hafnium (Hf), silver (Ag), chrome (Cr), gold (Au), molybdenum (Mo), silicon (Si), ruthenium (Ru), tantalum (Ta), tantalum nitride (TaN), tantalum carbide (TaC), titanium nitride (TiN), tungsten (W), tungsten nitride (WN), lanthanum (La), alumina (AIOₓ), lanthanum oxides (LaOₓ), nickel platinum alloys (NiPt), and titanium (Ti), and or combination thereof. Such processing chambers are available from Applied Materials located in Santa Clara, Calif. It is contemplated that other processing chambers including those from other manufacturers may be adapted to benefit from one or more of the embodiments of the disclosure described herein.

The processing chamber 200 includes a chamber body 201 having sidewalls 204, a bottom wall 206, and an upper process assembly 208 that enclose a processing region 210 or plasma zone. The chamber body 201 is typically fabricated from welded plates of stainless steel or a unitary block of aluminum. In one embodiment, the sidewalls comprise aluminum and the bottom portion of the chamber includes one or more walls that are formed from a stainless steel plate. The sidewalls 204 generally contain a slit valve (not shown) to provide for entry and egress of a substrate 205 from the processing chamber 200. Components in the upper process assembly 208 of the processing chamber 200 in cooperation with the grounded shield 260, pedestal assembly 220 and cover ring 270 confine the plasma formed in the processing region 210 to the region above the substrate 205.

A pedestal assembly 220 is supported from the bottom wall 206 of the processing chamber 200. The pedestal assembly 220 supports a deposition ring 268 along with the substrate 205 during processing. The pedestal assembly 220 is coupled to the bottom wall 206 of the processing chamber 200 by a lift mechanism 222, which is configured to move the pedestal assembly 220 between an upper processing position and lower transfer position. Additionally, in the lower transfer position, lift pins 223 are moved through the pedestal assembly 220 to position the substrate a distance from the pedestal assembly 220 to facilitate the exchange of the substrate with a substrate transfer mechanism disposed exterior to the processing chamber 200, such as a single blade robot (not shown). A bellows 224 is typically disposed between the pedestal assembly 220 and the bottom wall 206 to isolate the processing region 210 from the interior of the pedestal assembly 220 and the exterior of the chamber.

The pedestal assembly 220 generally includes a support 226 sealingly coupled to a platform housing 228. The platform housing 228 is typically fabricated from a metallic material such as stainless steel or aluminum. A cooling plate (not shown) is generally disposed within the platform housing 228 to thermally regulate the support 226.

The support 226 may be comprised of aluminum or ceramic. The substrate support 226 has a substrate receiving surface 227 that receives and supports the substrate 205 during processing, the substrate receiving surface 227 being substantially parallel to a sputtering surface 233 of the sputtering target 232. The support 226 also has a peripheral edge 229 that terminates before an overhanging edge 205A of the substrate 205. The support 226 may be an electrostatic chuck, a ceramic body, a heater or a combination thereof. In one embodiment, the support 226 is an electrostatic chuck that includes a dielectric body having an electrode 226A, embedded therein. The dielectric body is typically fabricated from a high thermal conductivity dielectric material such as pyrolytic boron nitride, aluminum nitride, silicon nitride, alumina or an equivalent material. Other aspects of the pedestal assembly 220 and support 226 are further described below. In one embodiment, the electrode 226A is configured so that when a DC voltage is applied to the electrode 226A, by an electrostatic chuck power supply 243, a substrate 205 disposed on the substrate receiving surface 227 will be electrostatically chucked thereto to improve the heat transfer between the substrate 205 and the support 226. In another embodiment, a bias source 241 is also coupled to the electrode 226A so that a voltage can be maintained on the substrate during processing to affect the plasma interaction with the surface of the substrate 205.

A program (or computer instructions) readable by the system controller 126 determines which tasks are performable on a substrate. Preferably, the program is software readable by the system controller 126 that includes code to perform tasks relating to monitoring, execution and control of the movement and various process recipe tasks and recipe steps being performed in the processing system 100 and processing chamber 200. For example, the system controller 126 can comprise program code that includes a substrate positioning instruction set to operate the pedestal assembly 220; a gas flow control instruction set to operate gas flow control valves to set a flow of sputtering gas to the processing chamber 200; a gas pressure control instruction set to operate a throttle valve or gate valve to maintain a pressure in the processing chamber 200; a temperature control instruction set to control a temperature control system (not shown) in the pedestal assembly 220 or sidewalls 204 to set temperatures of the substrate or sidewalls 204, respectively; and a process monitoring instruction set to monitor the process in the processing chamber 200.

The processing chamber 200 also contains a process kit 250 which comprises various components that can be easily removed from the processing chamber 200, for example, to clean sputtering deposits off the component surfaces, replace or repair eroded components, or to adapt the processing chamber 200 for other processes. In one embodiment, the process kit 250 comprises an isolator ring assembly 280, a grounded shield 260 and a deposition ring 268 for placement about a peripheral edge 229 of the support 226 that terminates before an overhanging edge of the substrate 205.

The upper process assembly 208 may also comprise an RF source 281, a direct current (DC) source 282, an adaptor 202, a motor 293, and a lid assembly 230. The lid assembly 230 generally comprises a sputtering target 232, a magnetron system 289 and a lid enclosure 291. The upper process assembly 208 is supported by the sidewalls 204 when in a closed position, as shown in FIG. 2A. A ceramic target isolator 236 is disposed between the isolator ring assembly 280, the sputtering target 232 and adaptor 202 of the lid assembly 230 to prevent vacuum leakage therebetween. The adaptor 202 is sealably coupled to the sidewalls 204, and is configured to help with the removal of the upper process assembly 208 and isolator ring assembly 280.

When in the processing position, the sputtering target 232 is disposed adjacent to the adaptor 202, and is exposed to the processing region 210 of the processing chamber 200. The sputtering target 232 contains material that is deposited on the substrate 205 during a PVD, or sputtering, process. The isolator ring assembly 280 is disposed between the sputtering target 232 and the shield 260 and chamber body 201 to electrically isolate the sputtering target 232 from the shield 260 and chamber body 201.

During processing, the sputtering target 232 is biased relative to a grounded region of the processing chamber (e.g., chamber body 201 and adaptor 202) by a power source disposed in the RF source 281 and/or the direct current (DC) source 282. It is believed that by delivering RF energy and DC power to the sputtering target 232 during a high pressure PVD process, significant process advantages can be achieved over conventional low pressure DC plasma processing techniques when used in conjunction with sputtering materials such as titanium, copper, nickel, ruthenium, aluminum, tantalum, molybdenum, and tungsten to name just a few. In one embodiment, the RF source 281 comprises an RF power source 281A and an RF match 281B that are configured to efficiently deliver RF energy to the sputtering target 232. In one example, the RF power source 281A is capable of generating RF currents at a frequency of between about 13.56 MHz and about 228 MHz at powers between about 0 and about 5 kWatts. In one example, the DC power supply 282A in the DC source 282 is capable of delivering between about 0 and about 50 kWatts of DC power.

In some embodiments, the processing chamber 200 also includes one or more auxiliary electromagnet assemblies vertically aligned around the processing chamber, such as a first electromagnet assembly 261, a second electromagnet assembly 263, a third electromagnet assembly 265. In some embodiments, the first, second, and third electromagnet assemblies each include a separate current source so that each assembly can separately generate a magnetic field that is configured to confine and/or control the movement of electrons and ions generated in a plasma formed in the processing region 210 of the processing chamber.

In some embodiments, the first electromagnet assembly 261 comprises a first current source 261A configured to bias a first magnetic coil assembly 261B. The first magnetic coil assembly 261B is positioned near the sputtering target 232, configured to modulate the magnetron controlled plasma 213. The second electromagnet assembly 263 comprises a second current source 263A configured to bias a second magnetic coil assembly 263B. The second magnetic coil assembly 263B is positioned in the central part of the chamber, and configured to modulate a central portion of the plasma 211. The third electromagnet assembly 265 comprises a third current source 265A configured to bias a third magnetic coil assembly 265B. The third magnetic coil assembly 265B is positioned near the support 226, configured to modulate the plasma near the surface of the substrate 205. In some configurations, the first, second, and third current sources 261A, 263A, and 265A are capable of generating a DC or RF current or voltage at a power between about 0 and about 5 kWatts.

In operation, the one or more electromagnet assemblies 261, 263, and 265 are vertically distributed and positioned outside the process kit 250 to generate magnetic field within the processing region 210 to help alter and/or shape the radial distribution of the plasma formed with the processing region 210 during processing. In some embodiments, the one or more electromagnet assemblies comprise a single electromagnet, a pair of electromagnets, or a quadruple electromagnet array. The quadruple electromagnet array includes four solenoidal coils wrapped generally circularly symmetrically about the central axis 294 of the processing chamber 200. In one configuration, the four electromagnets are configured as top inner magnet (TIM), top outer magnet (TOM), bottom inner magnet (BIM), and bottom outer magnet (BOM) (not shown). The magnetic field generated by the quadruple electromagnet array is modulated by controlling the direction and magnitude of electric current flowing through each coil, or selectively powering a particular combination of coils, e.g., the outer/inner coils or the top/bottom coils.

During processing, a gas, such as argon, is supplied to the processing region 210 from a gas source 242 via conduits 244. The gas source 242 may comprise an inert gas such as argon, krypton, helium or xenon, which is capable of energetically impinging upon and sputtering material from the sputtering target 232 and/or surface of the substrate 205 based on a bias applied by the bias source 241. The gas source 242 may also include a reactive gas, such as one or more of an oxygen-containing gas or a nitrogen-containing gas, which is capable of reacting with the sputtering material to form a layer on a substrate. Spent process gas and byproducts are exhausted from the processing chamber 200 through exhaust ports 246 that receive spent process gas and direct the spent process gas to an exhaust conduit 248 having an adjustable position gate valve 247 to control the pressure in the processing region 210 in the processing chamber 200. The exhaust conduit 248 is connected to one or more exhaust pump 249, such as a cryopump. Typically, the pressure of the sputtering gas in the processing chamber 200 during processing is set to sub-atmospheric levels, such as a vacuum environment, for example, a pressure of about 0.6 mTorr to about 400 mTorr. In one embodiment, the processing pressure is set to about 20 mTorr to about 100 mTorr. A plasma is formed between the substrate 205 and the sputtering target 232 from the gas. Ions within the plasma are accelerated toward the sputtering target 232 and cause material to become dislodged from the sputtering target 232. The dislodged target material is deposited on the substrate.

The lid enclosure 291 generally comprises a conductive wall 285, a center feed 284 and shielding 286 (FIG. 2A). In this configuration, the conductive wall 285, the center feed 284, the sputtering target 232 and a portion of the motor 293 enclose and form a back region 234. The back region 234 is a sealed region disposed on the back side of the sputtering target 232 and is generally filled with a flowing liquid during processing to remove the heat generated at the sputtering target 232 during processing. In one embodiment, the conductive wall 285 and center feed 284 are configured to support the motor 293 and magnetron system 289, so that the motor 293 can rotate the magnetron system 289 during processing. In one embodiment the motor 293 is electrically isolated from the RF or DC power delivered from the power supplies by use of a dielectric layer 293B, such as Delrin, G10, or Ardel.

The shielding 286 may comprise one or more dielectric materials that are positioned to enclose and prevent the RF energy delivered to the sputtering target 232 from interfering with and affecting other processing chambers disposed in the processing system 100 (FIG. 1). In one configuration, the shielding 286 may comprise a Delrin, G10, Ardel or other similar material and/or a thin grounded sheet metal RF shield.

To provide efficient sputtering, a magnetron system 289 is positioned in back of the sputtering target 232 in the upper process assembly 208 to create a magnetic field in the processing region 210 adjacent the sputtering surface 233 of the sputtering target 232, which creates a magnetron controlled plasma 213. The magnetic field by magnetron system 289 is created to trap electrons and ions to thereby increase the plasma density over one or more regions of the target 232, and to thereby also increase target utilization, control deposition uniformity and the sputtering rate. According to one embodiment of the disclosure, the magnetron system 289 includes a source magnetron assembly 221 that comprises an outer pole (not shown) and an inner pole (not shown). The magnetron system 289 is rotated about the central axis 294 of the processing chamber 200 by use of the motor 293. In some embodiments, a “closed loop” magnetron configuration is formed within the magnetron system 289 such that the outer pole (not shown) of the magnetron surrounds the inner pole (not shown) of the magnetron forming a gap between the poles that is a continuous loop. In the closed loop configuration, the magnetic fields that emerge and reenter through a surface of the sputtering target form a “closed loop” pattern can be used to confine electrons near the surface of the sputtering target in a closed pattern, which is often called a “racetrack” type pattern. A closed loop, as opposed to the open-loop, magnetron configuration is able to confine electrons and generate a high density plasma near the sputtering surface 233 of the sputtering target 232 to increase the sputtering yield. In some other embodiments, an “open loop” magnetron configuration is formed within the magnetron system 289 such that the outer pole of the magnetron surrounds the inner pole of the magnetron forming a gap between the poles that is a continuous loop. In an open loop magnetron configuration, the electrons trapped between the inner and outer poles will migrate, leak out and escape from the B-fields created at open ends of the magnetron, thus only holding the electrons for a short period of time during the sputtering process due to the reduced confinement of the electrons. It has been found that the use of an open loop magnetron configuration, can provide significant step coverage improvements and provide an improved material composition uniformity across the substrate surface, when used in conjunction with the RF and DC sputtering of multi-compositional targets described herein.

In some embodiments of the processing chamber 200, the bias source 241 is coupled between an electrode and RF ground to adjust the bias voltage on the substrate 205 during processing to control the degree of bombardment on the substrate surface. In some embodiments, the electrode is disposed adjacent to the substrate receiving surface 227 of a support 226, and comprises the electrode 226A. In a PVD reactor, tuning of the bombardment of the substrate surface by the control of the impedance of the electrode to ground, will affect step coverage, overhang geometry and deposited film's properties, such as grain size, film stress, crystal orientation, film density, roughness, feature bottom coverage, feature step coverage and in some cases can effect film composition. Therefore, the bias source 241 can thus be used to alter the deposition rate, the etching rate and even the composition of a multi-compositional film at the substrate surface. In one embodiment, the bias source 241 is employed to enable deposition or etching of a deposited film, by the appropriate adjustment of impedance of the electrode/substrate to ground. In one embodiment of the bias source 241, the bias source 241 that has a variable capacitor tuning circuit with a feedback circuit to control the properties of a deposited metal or non-metal layer on a substrate.

In some embodiments, the bias source 241 includes by an RF source (not shown) and an impedance match (not shown) that are coupled to the electrode 226A. In some embodiments, the RF power source is capable of generating RF currents at a frequency of between about 11 MHz and about 228 MHz, such as 13.56 MHz at powers between about 0 and about 5 kWatts.

### Biasable Flux Optimizer

In some embodiments, as shown in FIG. 2B, a processing chamber 200 is modified to include a biasable flux optimizer 290 for further control of the ion distribution and directionality in the chamber. The biasable flux optimizer 290 is also referred to herein as a collimator in some embodiments. In one implementation, a control over ion flux directionality of sputtered material may be achieved by positioning the biasable flux optimizer 290 between the sputtering target 232 and the pedestal assembly 220. A power source 251 is coupled to the biasable flux optimizer 290 to provide a bias potential to energize the biasable flux optimizer 290 and attract sputtered metal ions formed in the plasma.

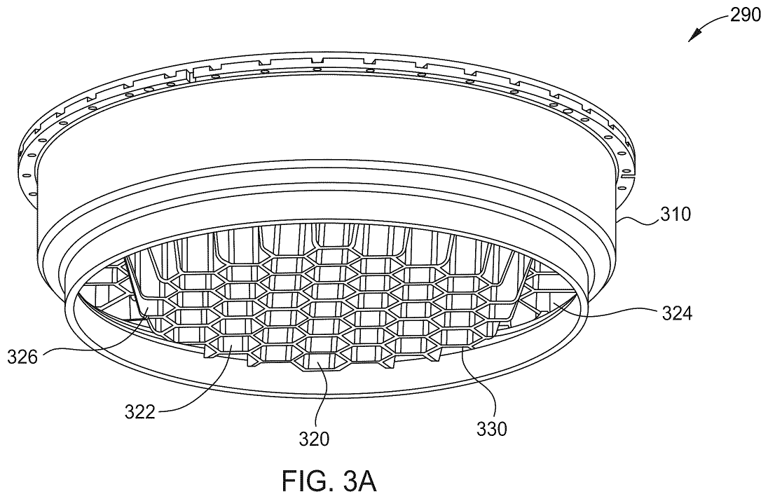

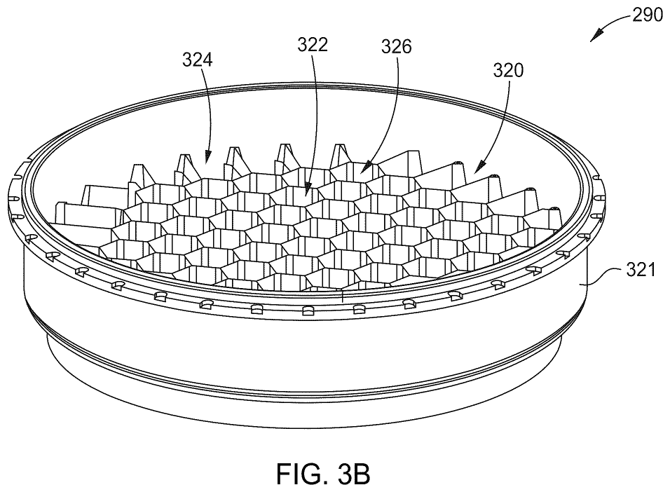

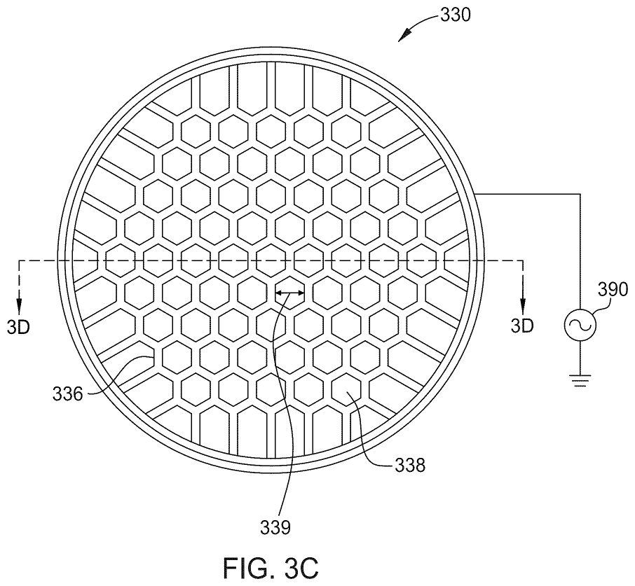

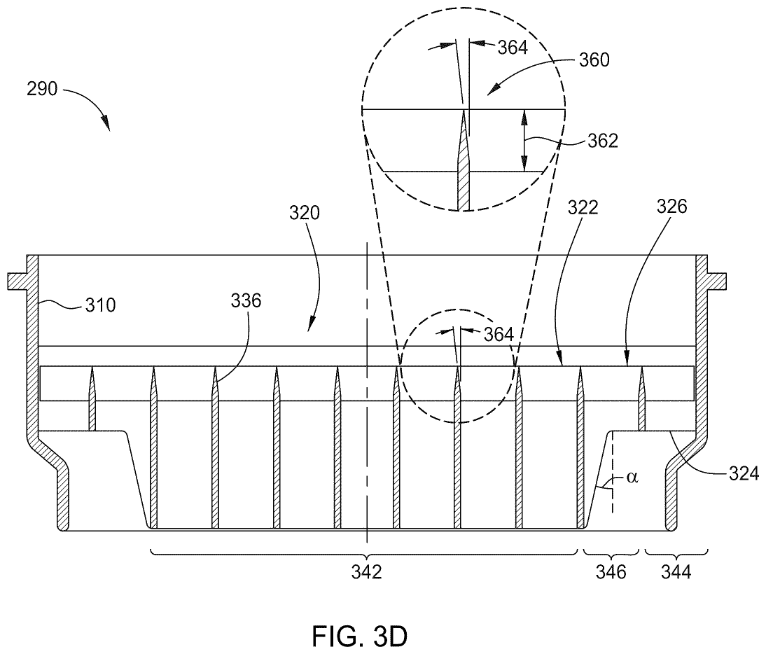

FIG. 3A depicts a perspective view of a biasable flux optimizer 290 in accordance with implementations of the present disclosure. FIG. 3B depicts another perspective view of the biasable flux optimizer 290 in accordance with implementations of the present disclosure. FIG. 3C depicts a top view of the biasable flux optimizer 290 of FIG. 3A-3B that may be disposed in the processing chamber 200 of FIG. 2B. The biasable flux optimizer 290 includes a shield portion 310 coupled with a collimator portion 320. The collimator portion 320 includes a plurality of apertures to direct and allow the passage of gas and/or material flux therethrough within the processing chamber 200.

The collimator portion 320 may be mechanically and electrically coupled to the one-piece shield portion 310. In one implementation, the collimator portion 320 is integral to the one-piece shield portion 320, as shown in FIGS. 3A-3B. In one implementation, the collimator portion 320 is welded to the one-piece shield portion 310. In one implementation, the collimator portion 320 and the one-piece shield portion 310 are machined from a single mass of material. In one implementation, the collimator portion 320 and the one-piece shield portion 310 are comprised of a material selected from aluminum, titanium, copper, and stainless steel. Alternatively, the one-piece shield portion 310 and the collimator portion 320 are formed as separate pieces and coupled together using suitable attachment means, such as bolting, riveting or welding. In one implementation, the collimator portion 320 may be electrically floating within the processing chamber 200. In one implementation, the collimator portion 320 may be coupled to an electrical power source.

As shown in FIG. 3C, the collimator portion 320 is generally a body or a honeycomb structure 330 having walls 336 defining and separating hexagonal aperture(s) 338 in a close-packed arrangement. An aspect ratio of the hexagonal apertures 338 may be defined as the depth of the hexagonal aperture 338 (equal to the thickness of the collimator) divided by the width 339 of the hexagonal aperture 338. In some embodiments, the thickness of the walls 336 is between about 0.1 mm and about 10 mm in either the lateral and/or cross-sectional direction, such as about 1 mm to about 7.5 mm, such as about 2.5 mm to about 5 mm, alternatively about 0.1 mm to about 1 mm, alternatively about 1 mm to about 2.5 mm, alternatively about 2.5 mm to about 3.5 mm, alternatively about 3.5 mm to about 5 mm, alternatively about 5 mm to about 7.5 mm, alternatively about 7.5 mm to about 10 mm. In one implementation, the collimator portion 320 is comprised of a material selected from aluminum, titanium, copper, and stainless steel.

The honeycomb structure 330 of the collimator portion 320 may serve as an integrated flux optimizer to improve the flow path, ion fraction, and ion trajectory behavior of ions passing through the collimator portion 320. In one implementation, the walls 336 adjacent to a shield portion have a tapered entrance portion and a radius. The one-piece shield portion 310 of the collimator portion 320 may assist in the installation of the collimator portion 320 into the processing chamber 200.

In one implementation, the collimator portion 320 may be machined from a single mass of aluminum. The collimator portion 320 may optionally be coated or anodized. Alternatively, the collimator portion 320 may be made from other materials compatible with the processing environment, and may be comprised of one or more sections. In some implementations, the walls 336 of the collimator portion 320 may be textured (e.g., bead blasted) to improve adhesion of high stress films (e.g., copper alloys) to the walls 336.

In one implementation, the collimator portion 320 may be electrically biased in bipolar mode to control the direction of the ions passing through the collimator portion 320. For example, as shown in FIG. 3C, a controllable direct current (DC) or alternating current (AC) power source 390 may be coupled to the collimator portion 320 to provide an alternating pulsed positive or negative voltage to the collimator portion 320 to bias the collimator portion 320.

The collimator portion 320 functions as a filter to trap ions and neutral species that are emitted from the material from the sputtering target 232 at angles exceeding a selected angle, near normal relative to the substrate 205. The hexagonal apertures 338 of the collimator portion 320 are designed to allow a different percentage of ions emitted from a center or a peripheral region of the material from the sputtering target 232 to pass through the collimator portion 320. As a result, both the number of ions and the angle of arrival of ions deposited onto peripheral regions and center regions of the substrate 205 are adjusted and controlled. Therefore, material may be more uniformly sputter deposited across the surface of the substrate 205. Additionally material may be more uniformly deposited on the bottom and sidewalls of high aspect ratio features, particularly high aspect ratio vias and trenches located near the periphery of the substrate 205.

FIG. 3D depicts a cross-sectional view of the biasable flux optimizer 290 of FIGS. 3A-3B in accordance with implementations of the present disclosure. The collimator portion 320 includes the body or honeycomb structure 330 having a central region 342 having a first plurality of apertures 322 with a high aspect ratio, such as from about 2.5:1 to about 3:1. The aspect ratio of a second plurality of apertures 324 of the collimator portion 320 in an outer peripheral region 344 decreases relative to the first plurality of apertures 322 in the central region 342. In one implementation, the second plurality of apertures 324 in the outer peripheral region 344 have an aspect ratio of from about 1:1 to about 2:1. In one implementation, the second plurality of apertures 324 in the outer peripheral region 344 has an aspect ratio of about 1:1. A higher aspect ratio allows for more apertures in the central region 342 of the collimator portion 320. In one implementation, the central region includes 61 apertures.

In one implementation, the radial decrease of the hexagonal apertures 338 is accomplished by providing a third plurality of apertures 326 in a transitional region 346 disposed between the central region 342 and the outer peripheral region 344. The walls 336 defining the third plurality of apertures 326 are cut along a predetermined angle “α” so that the transitional region 346 forms a conical shape surrounding the first plurality of apertures 322. In one implementation, the predetermined angle α is between 15 degrees and 45 degrees. The transitional region 346 advantageously provides a circular profile of apertures in the central region 342 that overcomes the six-point deposition near an edge of the substrate 205 due to shadowing caused by corners of a conventional hexagonal collimator.

Upper portions of the walls 336 defining the hexagonal apertures 338 have an entrance portion 360 to decrease a rate at which the hexagonal apertures 338 are clogged by sputtered material. The entrance portion 360 has a tapered shape. The entrance portion 360 extends a predetermined distance 362 into the hexagonal aperture 338 and is formed at a predetermined angle 364. In one implementation, the predetermined distance 362 is between about 0.15 inches (3.81 millimeters) to about 1 inch (2.54 centimeters) and the predetermined angle 364 is between about 2 degrees and about 16 degrees. In one implementation, the predetermined distance 362 and the predetermined angle 364 are about 1 inch (2.54 centimeters) and 2.5 degrees respectively.

### Dual Biasable Flux Optimizer

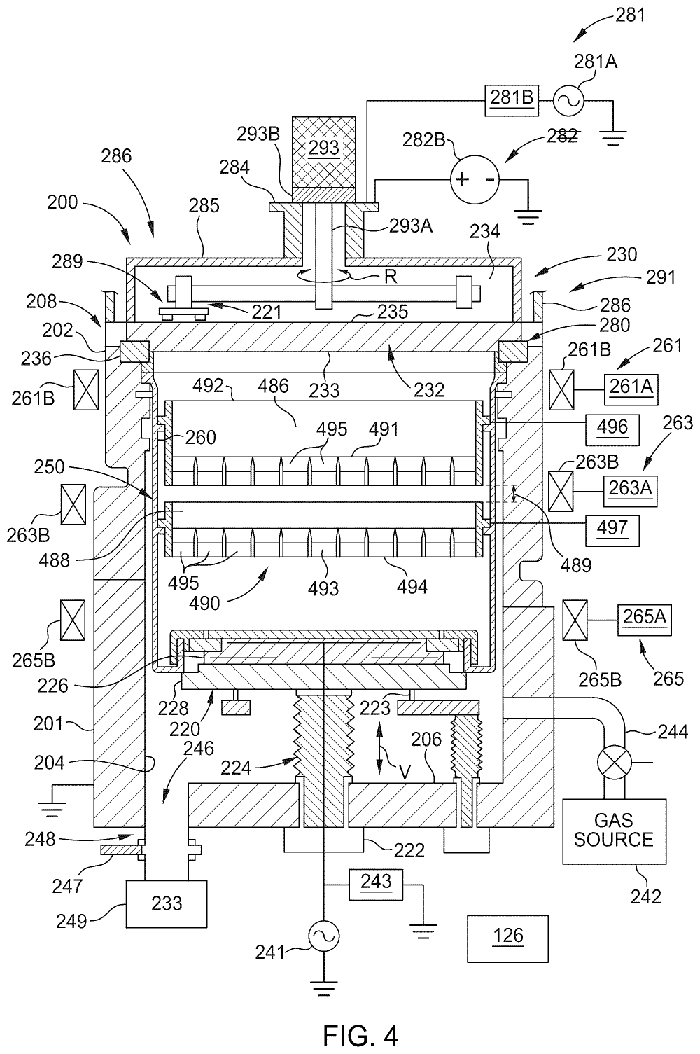

In some embodiments, as shown in FIG. 4, a processing chamber 200 is modified to include a biasable flux optimizer 490 for further control of the ion distribution and directionality in the chamber. FIG. 4 is a side cross-sectional view of the processing chamber 200 that depicts a second type of biasable flux optimizer 490 in accordance with implementations of the present disclosure. The biasable flux optimizer 490, which is referred to herein as a dual biasable flux optimizer, can be similarly positioned and similarly configured as the biasable flux optimizer 290 described above in relation to FIG. 2B. The biasable flux optimizer 490 includes a first biasable flux optimizer 492 and a second biasable flux optimizer 494. The first biasable flux optimizer 492 is electrically isolated from the second biasable flux optimizer 494, and is spaced a distance 489 from the second biasable flux optimizer 494. In one or more embodiments, the distance 489 separating the first biasable flux optimizer 492 from the second biasable flux optimizer 494 is about 10 cm or less, such as about 5 cm or less, such as about 1 cm or less, such as about 0.1 cm or less, such as about 0.01 cm or less. In some embodiments, distance 489 separating the first biasable flux optimizer 492 from the second biasable flux optimizer 494 is from about 0.01 cm to about 25 cm, such as about 0.1 cm to about 20 cm, such as about 1 cm to about 15 cm, such as about 10 cm to about 10 cm, alternatively about 0.01 cm to about 0.1 cm, alternatively about 0.1 cm to about 1 cm, alternatively about 1 cm to about 5 cm, alternatively about 10 cm to about 15 cm, alternatively about 15 cm to about 20 cm, alternatively about 20 cm to about 25 cm.

The collimator portion 491 of the first biasable flux optimizer 492 and the collimator portion 493 of the second biasable flux optimizer 494 both generally include a body structure having walls that define a plurality of apertures (e.g., hexagonal apertures 338) that include openings 495 that are used to direct and allow the passage of gas and sputtered material flux (e.g., ions and/or neutrals) therethrough within the processing chamber 200. The first biasable flux optimizer 492 will generally include an entrance portion 486 and a collimator portion 491. The second biasable flux optimizer 494 will generally include an entrance portion 488 and a collimator portion 493. In one example, a top view and cross-sectional view of the collimator portion 491 of the first biasable flux optimizer 492 and the collimator portion 493 of the second biasable flux optimizer 494 of the biasable flux optimizer 490 that may be disposed in the processing chamber 200 is illustrated in FIGS. 3C-3D. As illustrated in FIG. 4, the openings 495 within the plurality of apertures within first biasable flux optimizer 492 and the second biasable flux optimizer 494 are aligned to allow the gas and sputtered material flux (e.g., ions and/or neutrals) to pass therethrough.

In some implementations described herein, the biasable flux optimizer 490 is provided to further control ion distribution and directionality during the process. The ability to separately bias the separate flux optimizers (i.e., first biasable flux optimizer 492 and second biasable flux optimizer 494) allows control of the electric field through which the sputtered material species pass. In one embodiment, a first power source 496 is coupled to the first biasable flux optimizer 492 so as to supply a voltage to the first biasable flux optimizer 492, and a second power source 497 is coupled to the second biasable flux optimizer 494 so as to supply a voltage to the second biasable flux optimizer 494. In some alternate configurations, a relative bias is supplied between the first biasable flux optimizer 492 and the second biasable flux optimizer 494 by a power source (not shown) that coupled between the biasable flux optimizers 492, 494, while one of the biasable flux optimizers 492, 494 is coupled to a ground reference.

In one processing example, an opposing bias is applied between biasable flux optimizers 492, 494 during a deposition process, where a negative bias is applied to the second biasable flux optimizer 494 relative to the first biasable flux optimizer 492. In an alternate example of an opposing bias, a negative bias is applied to the first biasable flux optimizer 492 relative to the second biasable flux optimizer 494. In some embodiments, the opposing bias that is applied between the first biasable flux optimizer 492 and the second biasable flux optimizer 494 is applied in a pulsing, or alternating fashion to assist local deposition onto the substrate 205. The voltage pulse can include a series of asymmetric voltage pulses that have pulse on-time that is between 5% and 95% of the pulse period, such as between 25% and 75%. The voltage pulse can be provided at a frequency of between about 1 hertz (Hz) and 500 kHz. The first power source 496 and the second power source 497 are each configured to provide negative and/or positive voltage pulses to their respective biasable flux optimizer so as to control in uni-polar or bipolar mode as needed. In one embodiment, the biasable flux optimizer 490 is controlled in a bipolar mode to control and trap ions, so as to create different ratio of ions and neutrals passing through the biasable flux optimizer 490. Without being bound by theory, it is postulated that positive voltage pulses relative to ground applied to the first biasable flux optimizer 492 and/or second biasable flux optimizer 494 may draw electrons in the plasma towards the substrate surface and repel or slow the ion flux towards the substrate surface. While negative voltage pulses applied relative to ground to the first biasable flux optimizer 492 and/or second biasable flux optimizer 494 may repel electrons in the plasma towards the target and increase the ion flux towards the substrate surface. Therefore, by applying alternating positive and negative voltage pulses to the first biasable flux optimizer 492, the second biasable flux optimizer 494, or to both, directionality of the ions and neutrals passing through the biasable flux optimizer 490 may be efficiently controlled.

In some embodiments, at least one of the first biasable flux optimizer 492 and/or the second biasable flux optimizer 494 is configured to be electrically grounded such that no voltage can be applied thereto. In at least one embodiment, the first biasable flux optimizer 492 is electrically grounded such that no voltage can be applied thereto. In at least one embodiment, the second biasable flux optimizer 494 is electrically grounded such that no voltage can be applied thereto.

In one or more embodiments, a voltage of about 10 V to about 200 V is applied to the first biasable flux optimizer 492, such as about 50 V to about 150 V, such as about 70 V to about 120 V, alternatively about 10 V to about 50 V, alternatively about 50 V to about 70 V, alternatively about 70 V to about 100 V, alternatively about 100 V to about 120 V, alternatively about 120 V to about 150 V, alternatively about 150 V to about 200 V. In one or more embodiments, a voltage of about 10 V to about 200 V is applied to the second biasable flux optimizer 494, such as about 50 V to about 150 V, such as about 70 V to about 120 V, alternatively about 10 V to about 50 V, alternatively about 50 V to about 70 V, alternatively about 70 V to about 100 V, alternatively about 100 V to about 120 V, alternatively about 120 V to about 150 V, alternatively about 150 V to about 200 V.

In one embodiment, the DC bias power pulse from the first power source 496 and/or the second power source 497 may have a duty cycle between about 5 percent (e.g., 5 percent on and 95 percent off) to about 70 percent (e.g., 70 percent on and 30 percent off), such as between about 5 percent and about 50 percent, such as between about 15 percent to 45 percent, at a bias frequency between about 400 Hz and about 500 KHz. Alternatively, the cycle of the DC bias power pulsed to the first biasable flux optimizer 492 and/or second biasable flux optimizer 494 may be controlled by a predetermined number of time periods performed. For example, the DC bias power may be pulsed between about every 1 milliseconds and about every 100 milliseconds. It is noted that the duty cycle of the DC bias power pulsed to the first biasable flux optimizer 492 and/or second biasable flux optimizer 494 may be repeated as many times as needed. In one embodiment, the DC bias power may be controlled at between about 1 kW and about 10 kW.

In some alternate embodiments, an RF bias can be applied to either or both of the first biasable flux optimizer 492 and/or second biasable flux optimizer 494, wherein the frequency of the RF bias can be between 400 Hz and 60 MHZ, such as a frequency of between about 2 MHz and 13.56 MHz. In this configuration, the first power source 496 and the second power source 497 are configured to provide an RF bias to the first biasable flux optimizer 492 or second biasable flux optimizer 494, respectively. In some embodiments, an opposing RF bias is applied between the first biasable flux optimizer 492 and the second biasable flux optimizer 494. In one example, a first RF bias is applied to the first biasable flux optimizer 492 and a second RF bias is applied to the second biasable flux optimizer 494. In some embodiments, a bias that is applied between the first biasable flux optimizer 492 and the second biasable flux optimizer 494 is applied in a pulsing, or alternating fashion to assist local deposition onto the substrate 205.

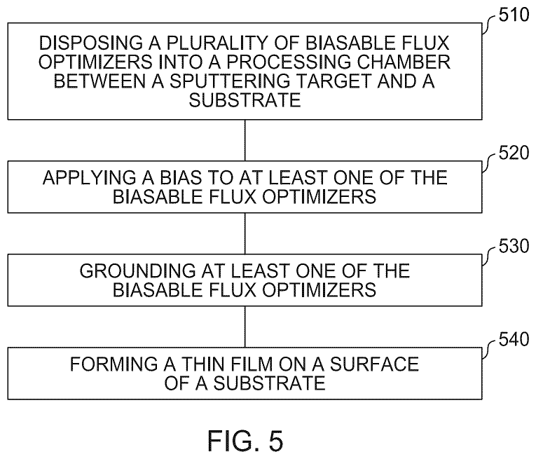

Generally, films may be deposited onto substrate surfaces using a processing chamber described via a method, such as the method 500 illustrated in FIG. 5. In operation 510 of the method 500, a plurality of biasable flux optimizers are positioned within a processing chamber between a sputtering target and a substrate. In operation 520 of the method 500, a bias is applied to at least one of the biasble flux optimizers. In operation 530 of the method 500, at least one of the biasable flux optimizers is electrically grounded such that no voltage can be applied thereto. In an alternate version of operation 530 of the method 500, at least one of the biasable flux optimizers is electrically biased relative to another biasble flux optimizer. In operation 540 of the method 500, a thin film is deposited onto the surface of a substrate.

Embodiments of the method 500 will include a method for depositing a film onto a substrate that includes applying a bias to at least one of a plurality of biasable flux optimizers disposed in a processing region of a processing chamber by supplying a voltage thereto, the voltage being supplied by a power source. At least one of the plurality of biasable flux optimizers is grounded, and the plurality of biasable flux optimizers are positioned within the processing region between a sputtering target and a substrate support. The process includes forming a film on a surface of a substrate disposed on the substrate support by sputtering a target material from the sputtering target by applying a bias to the target.

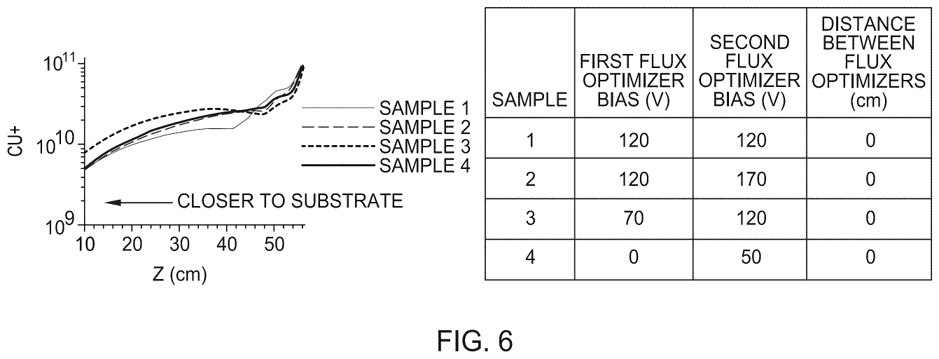

As previously discussed, a biasable flux optimizer 490 can include a first biasable flux optimizer 492 that is electrically isolated from a second biasable flux optimizer 494, and is spaced a distance 489 from the second biasable flux optimizer 494. Without being bound by theory, it has been found that the difference in voltage applied to the first biasable flux optimizer 492 and the second biasable flux optimizer 494 in combination the gap (e.g., distance 489) there between the two biasable flux optimizers can be used to control and tune the interaction of the plasma species (i.e., ions, electrons and neutrals) with the surface of the substrate during processing. More specifically, it was determined that when the bias voltage applied to the second biasable flux optimizer 494 is greater (e.g., more positive relative to ground) than the bias voltage applied to the first biasable flux optimizer 492, a greater ion fraction is present in the plasma closer to the substrate. This aspect is further exemplified in FIG. 6 when examining a copper sputtering process where a copper ion flux relative to the distance from the substrate is provided as illustrated in the figure, wherein the distance 489 between the first biasable flux optimizer 492 and the second biasable flux optimizer 494 is kept constant nominal distance apart, while the voltage applied to each of the biasable flux optimizers is systematically changed. As can be observed in FIG. 6, in each instance where the voltage applied to the second biasable flux optimizer 494 is greater than the voltage applied to the first biasable flux optimizer 492 (e.g., ΔV is a positive value), the ion content within the plasma is greater than when the same voltage is applied to both biasable flux optimizers (e.g., ΔV is 0).

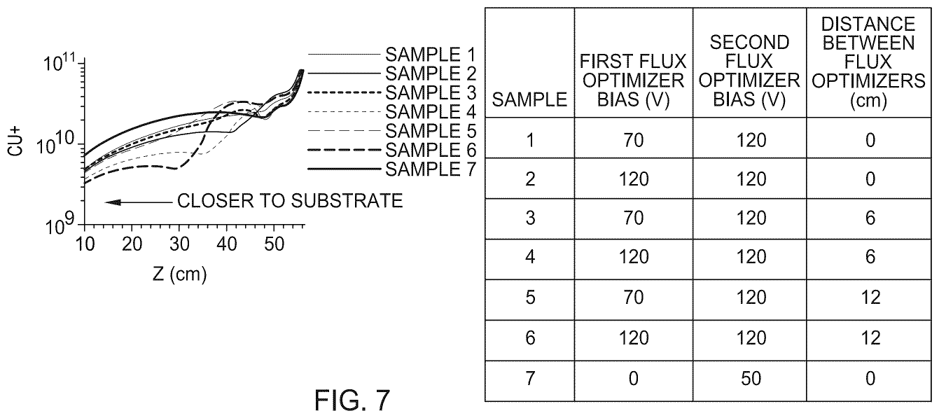

FIG. 7 illustrates the effects of adjusting the distances separating the first biasable flux optimizer 492 and the second biasable flux optimizer 494, in combination with the differences in applied biases. It was found that increasing the distance between the two biasable flux optimizers exaggerates the same trend of increasing the ion content in the plasma previously established in regards to ion flux resulting from differences in bias application.

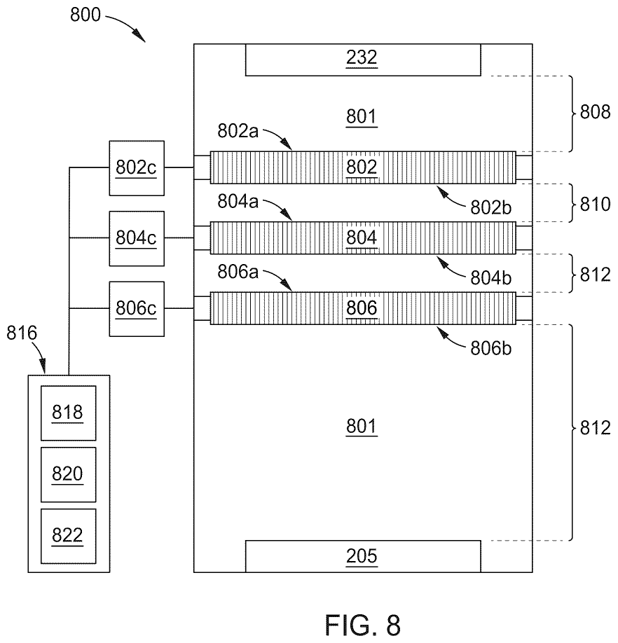

While the dual bias flux optimizer is described in the context of including a first biasable flux optimizer 492 and a second biasable flux optimizer 494, it should not limit the number of biasable flux optimizers that may be present in the biasable flux optimizer 490. For instance, the biasable flux optimizer 490 may include plurality of individual biasable flux optimizers, such as two or more biasable flux optimizers (e.g., a first biasable flux optimizer 492 and a second biasable flux optimizer 494) configured/oriented therein. FIG. 8 shows an illustration of a processing region 801 within a processing chamber 800 (such as a processing chamber 200), and including a top biasable flux optimizer 802, an intermediate biasable flux optimizer 804, and a bottom biasable flux optimizer 806. The top biasable flux optimizer 802 may include a first surface 802a and a second surface 802b. The first surface 802a of the top biasable flux optimizer 802 may be adjacent to the sputtering target 232 separated by a distance 808. The second surface 802b of the top biasable flux optimizer 802 may be adjacent to the intermediate biasable flux optimizer 804. The intermediate biasable flux optimizer 804 may include a first surface 804a and a second surface 804b. The first surface 804a of the intermediate biasable flux optimizer 804 may be adjacent to the second surface 802b of the top biasable flux optimizer 802 separated by a distance 810. The second surface 804b of the intermediate biasable flux optimizer 804 may be adjacent to the bottom biasable flux optimizer 806. The bottom biasable flux optimizer 806 may include a first surface 806a and a second surface 806b. The first surface 806a of the bottom biasable flux optimizer 806 may be adjacent to the second surface 804b of the intermediate biasable flux optimizer 804 separated by a distance 812. The second surface 806b of the bottom biasable flux optimizer 806 may be adjacent to the substrate 205 separated by a distance 814.

The top biasable flux optimizer 802 may be configured in accordance to any one or more flux optimizer configurations previously described. In at least one embodiment, the top biasable flux optimizer 802 is configured to be electrically grounded such that no voltage can be applied thereto. In at least one embodiment, the top biasable flux optimizer 802 is electrically biased by applying a voltage relative to ground thereto via a power source 802c. In one or more embodiments, a voltage of about 10 V to about 200 V is applied to the top biasable flux optimizer 802, such as about 50 V to about 150 V, such as about 70 V to about 120 V, alternatively about 10 V to about 50 V, alternatively about 50 V to about 70 V, alternatively about 70 V to about 100 V, alternatively about 100 V to about 120 V, alternatively about 120 V to about 150 V, alternatively about 150 V to about 200 V. As discussed above, in some embodiments, an RF bias can be applied to the top biasable flux optimizer 802.

In at least one embodiment, the first surface 802a of the top biasable flux optimizer 802 is separated from the sputtering target 232 by a distance 808 of about 800 mm or less, such as about 250 mm or less, such as about 100 mm or less, such as about 10 mm to about 500 mm, such as about 25 mm to about 250 mm, such as about 50 mm to about 100 mm, alternatively about 10 mm to about 25 mm, alternatively about 25 mm to about 50 mm, alternatively about 50 mm to about 75 mm, alternatively about 75 mm to about 100 mm, alternatively about 100 mm to about 250 mm, alternatively about 250 to about 500 mm. In at least one embodiment, the second surface 802b of the top biasable flux optimizer 802 is separated from the first surface 804a of the intermediate biasable flux optimizer 804 by a distance 810 of about 500 mm or less, such as about 250 mm or less, such as about 100 mm or less, such as about 10 mm to about 500 mm, such as about 25 mm to about 250 mm, such as about 50 mm to about 100 mm, alternatively about 10 mm to about 25 mm, alternatively about 25 mm to about 50 mm, alternatively about 50 mm to about 75 mm, alternatively about 75 mm to about 100 mm, alternatively about 100 mm to about 250 mm, alternatively about 250 to about 500 mm.

In some embodiments, the intermediate biasable flux optimizer 804 includes a plurality of individual biasable flux optimizers. The plurality of individual biasable flux optimizers can include any number of biasable flux optimizers, such as 1 to 50 biasable flux optimizers, such as 1 to 25 biasable flux optimizers, such as 1 to 10 biasable flux optimizers, such as 1 to 5 biasable flux optimizers, such as 1 to 2 biasable flux optimizers. Each of the plurality of individual biasable flux optimizers of the intermediate biasable flux optimizer 804 may be independently configured in accordance to any one or more flux optimizer configurations previously described. In at least one embodiment, each of the plurality of individual biasable flux optimizers of the intermediate biasable flux optimizer 804 are oriented in a stack configuration such that ions from the sputter target flow consecutively through each of the biasable flux optimizers (i.e., collimators). In at least one embodiment, each of the plurality of individual biasable flux optimizers of the intermediate biasable flux optimizer 804 are independently separated by a distance of about 500 mm or less, such as about 250 mm or less, such as about 100 mm or less, such as about 10 mm to about 500 mm, such as about 25 mm to about 250 mm, such as about 50 mm to about 100 mm, alternatively about 10 mm to about 25 mm, alternatively about 25 mm to about 50 mm, alternatively about 50 mm to about 75 mm, alternatively about 75 mm to about 100 mm, alternatively about 100 mm to about 250 mm, alternatively about 250 to about 500 mm.

In at least one embodiment, each of the plurality of individual biasable flux optimizers of the intermediate biasable flux optimizer 804 are independently biased by applying a voltage thereto via a power source 804c or electrically grounded such that no voltage can be applied thereto. In one or more embodiments, a voltage relative to ground of about 10 V to about 200 V is applied to one or more of the individual biasable flux optimizers of the intermediate biasable flux optimizer 804, such as about 50 V to about 150 V, such as about 70 V to about 120 V, alternatively about 10 V to about 50 V, alternatively about 50 V to about 70 V, alternatively about 70 V to about 100 V, alternatively about 100 V to about 120 V, alternatively about 120 V to about 150 V, alternatively about 150 V to about 200 V. As discussed above, in some embodiments, an RF bias can be applied to one or more of the intermediate biasable flux optimizers.

As previously discussed, the intermediate biasable flux optimizer 804 may include a first surface 804a and a second surface 804b. The first surface 504a of the intermediate biasable flux optimizer 804 may be adjacent to the second surface 802b of the top biasable flux optimizer 802 separated by a distance 810. In at least one embodiment, the first surface 804a of the intermediate biasable flux optimizer 804 is a surface of one of the individual biasable flux optimizers of the intermediate biasable flux optimizer 804 adjacent to the second surface 802b of the top biasable flux optimizer 802. The second surface 804b of the intermediate biasable flux optimizer 804 may be adjacent to the bottom biasable flux optimizer 806. In at least one embodiment, the second surface 804b of the intermediate biasable flux optimizer 804 is a surface of one of the individual biasable flux optimizers of the intermediate biasable flux optimizer 804 adjacent to the bottom biasable flux optimizer 806 and separated by a distance 812 of about 500 mm or less, such as about 250 mm or less, such as about 100 mm or less, such as about 10 mm to about 500 mm, such as about 25 mm to about 250 mm, such as about 50 mm to about 100 mm, alternatively about 10 mm to about 25 mm, alternatively about 25 mm to about 50 mm, alternatively about 50 mm to about 75 mm, alternatively about 75 mm to about 100 mm, alternatively about 100 mm to about 250 mm, alternatively about 250 to about 500 mm.

The bottom biasable flux optimizer 806 may be configured in accordance to any one or more flux optimizer configurations previously described. In at least one embodiment, the bottom biasable flux optimizer 806 is configured to be electrically grounded such that no voltage can be applied thereto. In at least one embodiment, the bottom biasable flux optimizer 806 is electrically biased by applying a relative voltage thereto via a power source 806c. In one or more embodiments, a voltage of about 10 V to about 200 V is applied to the top biasable flux optimizer 802, such as about 50 V to about 150 V, such as about 70 V to about 120 V, alternatively about 10 V to about 50 V, alternatively about 50 V to about 70 V, alternatively about 70 V to about 100 V, alternatively about 100 V to about 120 V, alternatively about 120 V to about 150 V, alternatively about 150 V to about 200 V. As discussed above, in some embodiments, an RF bias can be applied to the bottom biasable flux optimizer 806.

In at least one embodiment, the second surface 806b of the bottom biasable flux optimizer 806 is separated from the substrate 205 by a distance 814 of about 500 mm or less, such as about 250 mm or less, such as about 100 mm or less, such as about 10 mm to about 500 mm, such as about 25 mm to about 250 mm, such as about 50 mm to about 100 mm, alternatively about 10 mm to about 25 mm, alternatively about 25 mm to about 50 mm, alternatively about 50 mm to about 75 mm, alternatively about 75 mm to about 100 mm, alternatively about 100 mm to about 250 mm, alternatively about 250 to about 500 mm.

In some embodiments, the processing chamber 800 (such as a processing chamber 200) includes a power source 802c electrically coupled to the top biasable flux optimizer 802, a power source 804c electrically coupled to the intermediate biasable flux optimizer 804, and a power source 806c electrically coupled to the bottom biasable flux optimizer 806. Each of the power sources (e.g., power source 802c, power source 804c, and power source 806c) may be independently controlled by a controller 816, to independently establish the bias applied to one or more of the biasable flux optimizer (e.g., the top biasable flux optimizer 802, the intermediate biasable flux optimizer 804, the bottom biasable flux optimizer 806).

The controller 816 can be any type of controller used in an industrial setting, such as a programmable logic controller (PLC). The controller 816 includes a processor 818, a memory 820, and input/output (I/O) circuits 822. The controller 816 can further include one or more of the following components (not shown), such as one or more power supplies, clocks, communication components (e.g., network interface card), and user interfaces typically found in controllers for semiconductor equipment.

The memory 820 can include non-transitory memory. The non-transitory memory can be used to store the programs and settings described below. The memory 820 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 818 is configured to execute various programs stored in the memory 820, such as a program configured to execute the method 500 described in reference to FIG. 5. During execution of these programs, the controller 816 can communicate to I/O devices through the I/O circuits 822. For example, during execution of these programs and communication through the I/O circuits 822, the controller 816 can control outputs (e.g., independent application of biases applied to different flux optimizers).

Overall, the present disclosure provides an apparatus that includes one or more biasable flux optimizers design and methods forming thin films on a surface of a substrate. The one or more biasable flux optimizers may independently be supplied a voltage from one or more power supplies to maximize the ion fraction within the deposition plasma closer to the substrate during the deposition process. It was found that the ion content could be maximized by independently altering the bias applied to the biasable flux optimizers and by independently tuning the space there between. Additionally, the space between the sputter target and an adjacent biasable flux optimizer and/or the space between the substrate and biasable flux optimizer may also be tuned to further increase the ion fraction within the deposition plasma.

While the foregoing is directed to embodiments of the present disclosure, other and further embodiments of the disclosure may be devised without departing from the basic scope thereof, and the scope thereof is determined by the claims that follow.

What is claimed is:

1. A physical vapor deposition apparatus, comprising:
a substrate support disposed within a processing region of a processing chamber of the physical vapor deposition apparatus, wherein the substrate support comprises a substrate supporting surface;
a first flux optimizer disposed within the processing region, and comprising a plurality of apertures extending therethrough, the first flux optimizer being configured to be biased relative to a ground reference;
a second flux optimizer disposed within the processing region, and comprising a plurality of apertures extending therethrough, the second flux optimizer being configured to be biased relative to the ground reference, wherein the second flux optimizer is disposed between the first flux optimizer and the substrate support;
a first power source coupled to the first flux optimizer or the second flux optimizer, the first power source configured to supply a voltage to either the first flux optimizer or the second flux optimizer, wherein the first power source is configured to generate a bias voltage between the first flux optimizer and the second flux optimizer.

2. The physical vapor deposition apparatus of claim 1, wherein
the plurality of apertures in the first flux optimizer each comprise an opening that extends through the first flux optimizer,
the plurality of apertures in the second flux optimizer each comprise an opening that extends through the first flux optimizer, and
the plurality of apertures in the first and second flux optimizers are aligned.

3. The physical vapor deposition apparatus of claim 1, wherein a bias is applied to the first flux optimizer by supplying a voltage relative to ground to the first flux optimizer from the first power source.

4. The physical vapor deposition apparatus of claim 3, wherein the second flux optimizer is electrically grounded.

5. The physical vapor deposition apparatus of claim 1, wherein a bias is applied to the second flux optimizer by supplying a voltage to the second flux optimizer from the first power source.

6. The physical vapor deposition apparatus of claim 4, wherein the first flux optimizer is electrically grounded.

7. The physical vapor deposition apparatus of claim 1, wherein
the first power source is coupled to the first flux optimizer,
a second power source is coupled to the second flux optimizer, and
a first bias is applied to the first flux optimizer by supplying a voltage to the first flux optimizer from the first power source and wherein a second bias is applied to the second flux optimizer by supplying a voltage to the second flux optimizer from the second power source.

8. The physical vapor deposition apparatus of claim 6, wherein a negative bias is supplied to the first flux optimizer relative to the second flux optimizer.

9. The physical vapor deposition apparatus of claim 6, wherein a positive bias is supplied to the first flux optimizer relative to the second flux optimizer.

10. A physical vapor deposition apparatus, comprising:
a top flux optimizer configured to be biased;
an intermediate flux optimizer configured to be biased, wherein the top flux optimizer and the intermediate flux optimizer are separated by a first distance;
a bottom flux optimizer configured to be biased, wherein the bottom flux optimizer and the intermediate flux optimizer are separated by a second distance;
a top power source coupled to the top flux optimizer;
an intermediate power source coupled to the intermediate flux optimizer; and
a bottom power source coupled to the bottom flux optimizer.

11. The physical vapor deposition apparatus of claim 10, wherein
the first and second distances are between about 0.01 cm and 25 cm;
the intermediate flux optimizer comprises a plurality of biasable flux optimizers, and are separated from each other by a third distance that is about 0.01 cm and about 25 cm.

12. The physical vapor deposition apparatus of claim 11, wherein a bias is applied to at least one of the intermediate flux optimizers by supplying a voltage to the at least one biasable flux optimizer from the intermediate power source.

13. The physical vapor deposition apparatus of claim 11, wherein the plurality of biasable flux optimizers are independently biasable.

14. The physical vapor deposition apparatus of claim 10, wherein at least one of the top flux optimizer, the intermediate flux optimizer, and the bottom flux optimizer is electrically grounded.

15. The physical vapor deposition apparatus of claim 10, wherein a voltage of about 10 V to about 200 V is supplied to the top flux optimizer from the top power source.

16. The physical vapor deposition apparatus of claim 10, wherein a voltage of about 10 V to about 200 V is supplied to the bottom flux optimizer from the bottom power source.

17. A method for depositing a film onto a substrate, the method comprising:
applying a bias to at least one of a plurality of biasable flux optimizers disposed in a processing region of a processing chamber by supplying a voltage thereto, the voltage being supplied by a power source, wherein
at least one of the plurality of biasable flux optimizers is grounded, and
the plurality of biasable flux optimizers are positioned within the processing region between a sputtering target and a substrate support; and
forming a film on a surface of a substrate disposed on the substrate support by sputtering a target material from the sputtering target by applying a bias to the target.

18. The method of claim 17, wherein the plurality of biasable flux optimizers comprise a first flux optimizer and a second flux optimizer.

19. The method of claim 18, wherein the first flux optimizer is grounded and the second flux optimizer is biased.

20. The method of claim 18, wherein a voltage is supplied to both the first flux optimizer and the second flux optimizer, the voltage supplied to the second flux optimizer being greater than the voltage supplied to the first flux optimizer.
